(19) United States
(12) Patent Application Publication
(10) Pub. No.: US 2004/0229472 A1
(43) Pub. Date: Nov. 18, 2004

(54) Exposure mask pattern formation method, exposure mask, and semiconductor device production method employing the exposure mask

(75) Inventor: Shinji Kobayashi, Nara-shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/843,673

(22) Filed: May 12, 2004

(30) Foreign Application Priority Data
May 13, 2003 (JP) 2003-134827

(51) Int. Cl. G03C 5/00; H01L 21/302; H01L 21/461

(52) U.S. Cl. 438/736

(57) ABSTRACT

An exposure mask pattern formation method including the steps of: (a) providing actual pattern data for an actual pattern of an exposure mask having a light-blocking portion and a transmissive portion; (b) making first pattern data for a first pattern by uniformly enlarging the light-blocking portion of the actual pattern by a first length; (c) making dummy pattern data for a dummy pattern by reversing a light-blocking portion and a transmissive portion of the first pattern; (d) making pattern data for a first exposure mask by superposing the dummy pattern on the actual pattern, wherein the dummy pattern is spaced a distance not greater than the first length from an outer periphery of the light-blocking portion of the actual pattern in the first exposure mask; and (e) forming a first exposure mask pattern on the basis of the pattern data generated in the step (d).

### CROSS-REFERENCE TO RELATED APPLICATION

This application is related to Japanese application No. 2003-134827 filed on May 13, 2003, whose priority is claimed under 35 USC §119, the disclosure of which is incorporated by reference in its entirety.

### BACKGROUND OF THE INVENTION

1. Field of the Invention

The present invention relates to an exposure mask pattern formation method, an exposure mask, and a semiconductor device production method employing the exposure mask.

2. Description of the Related Art

The photolithography technique significantly contributes to the recent microminiaturization of circuit patterns of semiconductor devices. Particularly, the microminiaturization is realized by the reduction of the wavelength of exposure light. A relationship between a processing dimension on a semiconductor wafer and the exposure light wavelength of a light source employed in a photolithography process is shown in FIG. 19. In FIG. 19, a solid line (a) indicates a plot of the exposure light wavelength employed for the processing of the semiconductor wafer with respect to the processing dimension on the abscissa, and a broken line (b) indicates a reference line on which the processing dimension is equal to the exposure light wavelength. Where the processing dimension is 250 nm or greater, the processing dimension is generally equal to or greater than the exposure light wavelength as shown in FIG. 19 (the exposure light wavelength (solid line) is plotted on or below the reference line (broken line)). Where the processing dimension is 250 nm or smaller, on the other hand, the processing dimension is smaller than the exposure light wavelength. That is, the wafer is processed by employing an exposure light wavelength greater than a processing dimension in the latter case. This is because it is difficult to develop a short-wavelength photo-exposure apparatus, making the photo-exposure apparatus more costly. To cope with this, resolution improving techniques have been developed which do not rely on the reduction of the wavelength.

A phase shifting method is known as one of the resolution improving techniques. In this method, the contrast of light projected on the wafer is improved by phase-inverting a part of the incident light by means of a phase controlling member (generally referred to as “shifter”) provided on a mask. On a broader sense, there are currently two types of phase shifting methods: a Levenson method; and a halftone method. The Levenson method ensures an improved resolution in formation of a regularly repeated pattern. However, this method is not effective for formation of an isolated pattern having no regularity. On the other hand, the halftone method ensures an improved resolution in the formation of the isolated pattern. In the halftone method, a halftone mask has a translucent light-blocking pattern and a transmissive portion, and light rays passing through the transmissive portion of the mask is phase-shifted, whereby the light rays overlap with each other on the peripheral edges of the pattern and counteract each other. Thus, the contrast on the peripheral edges is improved, thereby improving the resolution in the formation of the isolated pattern.

Further, a modified illumination technique is employed for photo-exposure with the use of the halftone mask. This is known to be effective for improving a focus margin, i.e., for increasing an allowable defocusing range which permits the resulting photoresist pattern to have dimensions within an allowable range. FIG. 20(a) is a diagram for explaining an ordinary illumination technique, and FIG. 20(b) is a diagram for explaining the principles and effects of the modified illumination technique. The ordinary illumination technique (FIG. 20(a)) utilizes three-beam interference, while the modified illumination technique (FIG. 20(b)) utilizes two-beam interference for the improvement of the focus margin. FIG. 20(c) illustrates defocusing with respect to a wafer surface. In the three-beam interference caused by the ordinary illumination, an optical path difference due to defocusing of a 0-order beam is given by a difference d0-d0′ between a distance d0 from a point L0 to a point F and a distance d0′ from the point L0 to a point F′. An optical path difference due to defocusing of a +1-order beam is given by a difference d1-d1′ between a distance d1 from a point L1 to the point F and a distance d1′ from the point L1 to the point F′. Similarly, an optical path difference due to defocusing of a −1-order beam is given by a distance difference d2-d2′, which is equal to the optical path difference d1-d1′ due to the defocusing of the −1-order beam. Interference occurring due to an optical path difference (d0-d0′)-(d1-d1′) between the 0-order beam and the ±1-order beam reduces the contrast. In the two-beam interference caused by the modified illumination, on the other hand, an optical path difference due to defocusing of a 0-order beam is given by a difference d2-d2′ between a distance d2 from a point L2 to the point F and a distance d2′ from the point L2 to the point F′. Therefore, an optical path difference between the 0-order beam and the −1-order beam in the modified illumination is given by (d2-d2′)-(d1-d1′), which is theoretically zero. Hence, the reduction in contrast is suppressed. However, an intensity balance between the interfering beams is not appropriate because the two beams involved in the two-beam interference are the 0-order beam and one of the 1-order beams (the −1-order beam in FIG. 20(c)). Therefore, where the modified illumination is applied to a commonly employed chromium mask, the margin of the exposure light amount (the range of the exposure light amount which permits the photoresist pattern to have dimensions within the allowable range) tends to be reduced. With the modified illumination, the halftone mask is often employed for providing a proper intensity balance between the interfering beams, i.e., for increasing the intensity of the 1-order beam. With the use of the halftone mask, an opposite phase beam (having an opposite phase with respect to a beam transmitted through the transmissive portion) leaked from a halftone portion has the same phase as the 1-order beam. Thus, the intensity of the 1-order beam is increased, whereby the intensities of the two beams interfering with each other are equally balanced.

Since the modified illumination is associated with interference of light rays caused by diffraction, the focus margin is drastically improved in the case of a repeated line-and-space pattern (hereinafter referred to as “L/S pattern”) which is significantly influenced by the diffraction. However, the modified illumination is not effective for an isolated pattern. Where the ordinary illumination is employed together with the halftone mask, the focus margin is 0.6 μm for the L/S pattern and for the isolated pattern. On the other hand, where the modified illumination is employed, the focus margin is improved as shown in FIG. 21. In FIG. 21, a solid line (c) indicates a defocusing characteristic for the L/S pattern, and a broken line (d) indicates a defocusing characteristic for the isolated pattern. In FIG. 21, the allowable range of the photoresist pattern dimension is indicated by D1. The focus margin for the L/S pattern, which corresponds to a maximum width D2 of an allowable defocusing range of the line (c) within the allowable range defined by D1, is increased to 1.8 μm. On the other hand, the focus margin for the isolated pattern, which corresponds to a maximum width D3 of an allowable defocusing range of the line (d) within the allowable range defined by D1, is still 0.6 μm. Since an LSI chip generally has a pattern including an L/S pattern and an isolated pattern in combination, the modified illumination technique is not practical without effects on both the L/S pattern and the isolated pattern.

In this connection, an assist bar technique is known as one method for improving the focus margin for both the L/S pattern and the isolated pattern (see, for example, Japanese Unexamined Patent Publication No. Hei 7-273013 (1995)). In this technique, a dummy pattern for an assist bar having a proper size is disposed at a proper position adjacent to the isolated pattern, whereby the isolated pattern is regarded as a part of an L/S pattern. This makes it possible to provide a focus margin comparable to that for the L/S pattern. If the assist bar is formed as having a fine pattern which does not permit formation of a photoresist pattern, there is no need to remove the assist bar in a later step, but it is difficult to provide an effect comparable to that on the L/S pattern.

In this connection, another assist bar technique is disclosed, in which a dummy pattern having an increased size which permits formation of a photoresist pattern corresponding to the dummy pattern is disposed in the vicinity of an isolated pattern, and the photoresist pattern corresponding to the dummy pattern is removed in the second photo-exposure (see, for example, Japanese Unexamined Patent Publication No. Hei 10-326006 (1998)). With this technique, the focus margin for the isolated pattern is comparable to that for the L/S pattern. Further, the focus margin for the L/S pattern can also effectively be increased by providing a dummy pattern in parallel and close relation to a line pattern disposed at an end of the L/S pattern.

For the application of any of the aforesaid resolution improving techniques in the photolithography, there is a demand for a method for automatically forming an exposure mask pattern suitable for the resolution improving technique by simple graphic processing.

Further, there is a problem such that distal portions of respective line patterns of the L/S pattern are shrunk due to the influence of diffracted light rays as shown in FIGS. 22 and 23. Where the line patterns each have a width X of 160 nm, for example, the shrinkage of each of the distal portions with respect to the mask pattern is 50 nm to 80 nm. For accurate formation of the photoresist pattern, there is a demand for a method for suppressing the shrinkage.

Furthermore, it is known that the etching rate is reduced in a portion of the photoresist pattern having a higher pattern density in an etching process to be performed after the photo-exposure (hereinafter referred to as “loading effect”). For accurate formation of the photoresist pattern, there is a demand for a method for suppressing the loading effect to make the etching rate uniform.

### SUMMARY OF THE INVENTION

According to an aspect of the present invention, there is provided an exposure mask pattern formation method for forming an exposure mask pattern. The exposure mask pattern formed by the method of the present invention comprises a first exposure mask pattern for preparing a first exposure mask. The exposure mask pattern may father comprise a second exposure mask pattern for forming a second exposure mask which is used in combination with the first exposure mask.

According to the present invention, there is provided an exposure mask pattern formation method, which comprises the steps of: (a) providing actual pattern data for an actual pattern of an exposure mask having a light-blocking portion and a transmissive portion; (b) making first pattern data for a first pattern by graphic processing of the actual pattern data for uniformly enlarging the light-blocking portion of the actual pattern by a first length; (c) making dummy pattern data for a dummy pattern by graphic processing of the first pattern data for reversing a light-blocking portion and a transmissive portion of the first pattern; (d) making pattern data for a first exposure mask by graphic processing of the actual pattern data and the dummy pattern data for superposing the dummy pattern on the actual pattern, wherein the dummy pattern at its outer periphery opposing to the light-blocking portion of the actual pattern is spaced a distance not greater than the first length from an outer periphery of the light-blocking portion of the actual pattern in the first exposure mask; and (e) forming a first exposure mask pattern on the basis of the pattern data made in the step (d).

By this method, the exposure mask pattern suitable for the resolution improving technique can automatically be formed by simple graphic processing.

Since the first exposure mask pattern is formed as having the dummy pattern spaced the distance not greater than the first length from the outer periphery of the actual pattern, interference between light rays leaked from a halftone portion located around the light-blocking portion of the actual pattern and 1-order diffracted light rays occurs in a similar manner to the interference occurring in the case of the L/S pattern. Thus, focus margins for both an L/S pattern and an isolated pattern are improved, and light rays diffracted at distal portions of line patterns are corrected to suppress the shrinkage of the distal portions. Further, the pattern density around the actual pattern is made uniform as in the case of the L/S pattern by the provision of the dummy pattern, so that an etching dimensional error attributable to the loading effect can be suppressed.

### BRIEF DESCRIPTION OF THE DRAWINGS

FIGS. 1 to 4 are diagrams for explaining formation of a first exposure mask pattern according to a first embodiment of the present invention;

FIGS. 5 and 6 are diagrams for explaining formation of a second exposure mask pattern according to the first embodiment of the invention;

FIG. 7 is an explanatory diagram illustrating the first and second exposure mask patterns superposed one on another according to the first embodiment of the invention;

FIG. 8 is a flow chart for explaining a process for forming the first and second exposure mask patterns according to the first embodiment of the invention;

FIGS. 9 to 15 are diagrams for explaining formation of a first exposure mask according to a second embodiment of the invention;

FIG. 16 is a diagram for explaining formation of a second exposure mask according to the second embodiment of the invention;

FIG. 17 is an explanatory diagram illustrating the first and second exposure mask patterns superposed one on another according to the second embodiment of the invention;

FIG. 18 is a flow chart for explaining a process for forming the first and second exposure mask patterns according to the second embodiment of the invention;

FIG. 19 is a graph illustrating a relationship between a processing dimension on a semiconductor wafer and the exposure light wavelength of a light source employed in a photolithography process;

FIGS. 20(a), 20(b) and 20(c) are diagrams for explaining the principles and effects of known modified illumination;

FIG. 21 is a diagram for explaining a focus margin improving effect provided when the known modified illumination is employed;

FIG. 22 is a diagram for explaining the shrinkage of distal portions of line patterns in formation of a pattern including a dummy pattern according to the prior art;

FIG. 23 is an enlarged partial view of FIG. 22;

FIG. 24 is a diagram for explaining the suppression of the shrinkage of a distal portion of a line pattern according to the first embodiment of the invention;

FIG. 25 is an enlarged partial view of FIG. 24;

FIG. 26 is a diagram for explaining the suppression of the shrinkage of a distal portion of a line pattern according to the second embodiment of the invention; and

FIG. 27 is an enlarged partial view of FIG. 26.

### DETAILED DESCRIPTION OF THE INVENTION

In view of the foregoing, the present invention is directed to a mask pattern formation method for automatically forming an exposure mask pattern suitable for the resolution improving technique by simple graphic processing, an exposure mask, and a semiconductor device production method employing the exposure mask.

A pattern for an exposure mask to be used for photolithography is formed, for example, by means of a CAD known to those skilled in the art for designing the layout of a semiconductor device. In the CAD, data of the mask pattern includes, for example, graphical data indicative of a boundary between a light-blocking portion and a transmissive portion disposed within a plane, and information for determining whether a given point in the plane belongs to the light-blocking portion or the transmissive portion. The graphical data of the boundary may be stored as a set of coordinates of vertexes of the pattern. The graphical data is herein referred to as pattern data.

Inventive exposure mask pattern formation methods include a method of forming a first exposure mask pattern suitable for the exposure light resolution improving technique and, optionally, a method of forming a second exposure mask pattern for selectively removing a photoresist latent image or a photoresist pattern corresponding to a dummy pattern of the first exposure mask.

According to a first aspect of the present invention, there is provided an exposure mask pattern formation method, which comprises the steps of: (a) providing actual pattern data for an actual pattern of an exposure mask having a light-blocking portion and a transmissive portion; (b) making first pattern data for a first pattern by graphic processing of the actual pattern data for uniformly enlarging the light-blocking portion of the actual pattern by a first length; (c) making dummy pattern data for a dummy pattern by graphic processing of the first pattern data for reversing a light-blocking portion and a transmissive portion of the first pattern; (d) making pattern data for a first exposure mask by graphic processing of the actual pattern data and the dummy pattern data for superposing the dummy pattern on the actual pattern, wherein the dummy pattern at its outer periphery opposing to the light-blocking portion of the actual pattern is spaced a distance not greater than the first length from an outer periphery of the light-blocking portion of the actual pattern in the first expose mask; and (e) making a first exposure mask pattern on the basis of the pattern data made in the step (d).

The method may further comprise the steps of: (f) making pattern data for a second exposure mask including a transmissive portion entirely covering a region thereof corresponding to the dummy pattern of the first exposure mask by graphic processing of the first pattern data for uniformly reducing the light-blocking portion of the first pattern by a second length; and (g) forming a second exposure mask pattern on the basis of the pattern data made in the step (f).

According to a second aspect of the present invention, there is provided an exposure mask pattern formation method, which comprises the steps of: (a) providing actual pattern data for an actual pattern of an exposure mask including a light-blocking portion and a transmissive portion; (b) making first pattern data for a first pattern by graphic processing of the actual pattern data for uniformly enlarging the light-blocking portion of the actual pattern by a first length (L1); (c) making first dummy pattern data for a first dummy pattern by graphic processing of the first pattern data for reversing a light-blocking portion and a transmissive portion of the first pattern; (d) making second pattern data for a second pattern by graphic processing of the first pattern data for uniformly reducing the light-blocking portion of the first pattern by a second length (L2); (e) making third pattern data for a third pattern by graphic processing of the second pattern data for uniformly reducing a light-blocking portion of the second pattern by a third length (L3); (f) making second dummy pattern data for a second dummy pattern by graphic processing of the second pattern data and the third pattern data for extracting a disparity between the second pattern and the third pattern; (g) making pattern data for a first exposure mask by graphic processing of the actual pattern data, the first dummy pattern data and the second dummy pattern data for superposing the first dummy pattern and the second dummy pattern on the actual pattern, wherein the second dummy pattern is spaced a distance L1-L2-L3 from an outer periphery of the light-blocking portion of the actual pattern and has a linear light-blocking portion having a width of not greater than L2, and the first dummy pattern at its outer periphery opposing to the light-blocking portion of the second dummy pattern is spaced a distance L2 from the outer periphery of the second dummy pattern in the first exposure mask; and (h) forming a first exposure mask pattern on the basis of the pattern data made in the step (g).

The method may further comprise the steps of: (i) making pattern data for a second exposure mask including a transmissive portion entirely covering a region thereof corresponding to the first and second dummy patterns of the first exposure mask by graphic processing of the third pattern data for uniformly reducing a light-blocking portion of the third pattern by a fourth length; and (j) forming a second exposure mask pattern on the basis of the pattern data made in the step (i).

In the inventive exposure mask pattern formation method, the sum of the second length L2 and the third length L3 is not greater than the first length L1.

According to a third aspect of the present invention, there is provided a first exposure mask which has a mask pattern formed by employing the first exposure mask pattern formed by the aforesaid method.

According to a fourth aspect of the present invention, there is provided a second exposure mask which has a mask pattern formed by employing the second exposure mask pattern formed by the aforesaid method.

According to a fifth aspect of the present invention, there is provided a semiconductor device production method utilizing photolithography, the method comprising the steps of: forming first and second exposure masks by employing exposure mask patterns formed by either of the aforesaid methods; subjecting a photoresist layer on a semiconductor wafer to first photo-exposure with the use of the first exposure mask; and subjecting the photoresist layer on the semiconductor wafer to second photo-exposure with the use of the second exposure mask.

In the production method, the second photo-exposure step is performed after the first photo-exposure step, and the production method may further comprise the step of, after the second photo-exposure step, selectively etching away the photoresist layer according to a latent image formed in the photoresist layer as a result of the first photo-exposure and the second photo-exposure to form a photoresist pattern corresponding to an actual pattern of the first exposure mask on the semiconductor wafer.

Alternatively, the production method may further comprise the steps of: after the first photo-exposure step, selectively etching away the photoresist layer according to a latent image formed in the photoresist layer in the first photo-exposure step to form photoresist patterns corresponding to an actual pattern and a dummy pattern of the first exposure mask; and, after the second exposure step, selectively etching away the photoresist layer according to a latent image formed in the photoresist layer in the second photo-exposure step to selectively remove the photoresist pattern corresponding to the dummy pattern.

### DESCRIPTION OF THE PREFERRED EMBODIMENTS

With reference to the attached drawings, the present invention will be described in detail by way of embodiments thereof. It should be noted that the invention be not limited to these embodiments.

### First embodiment

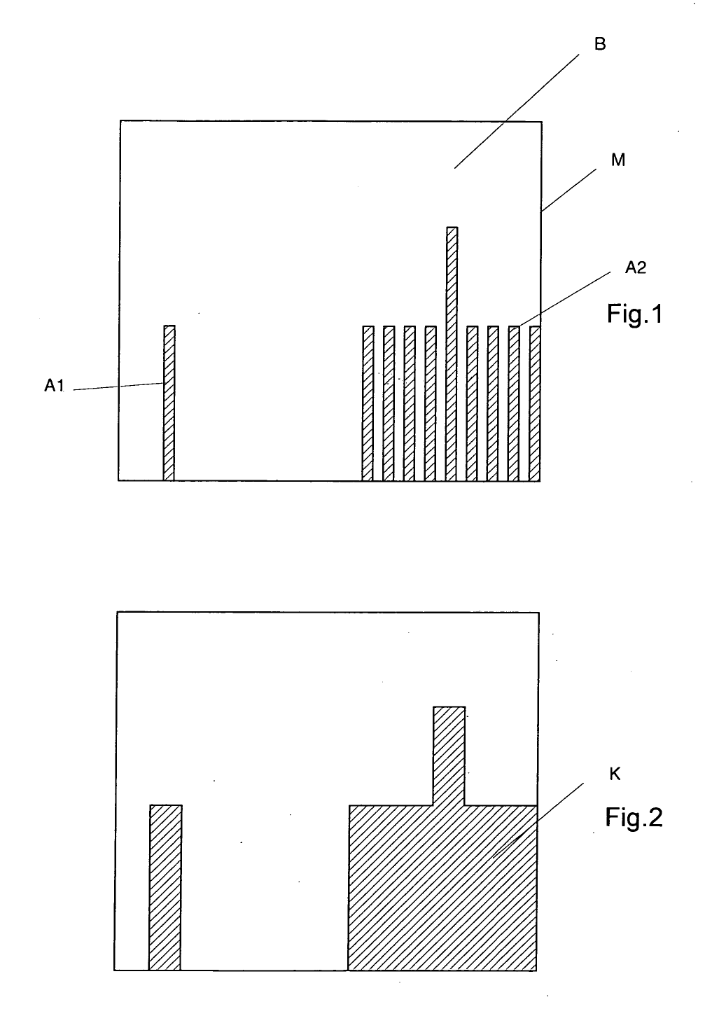

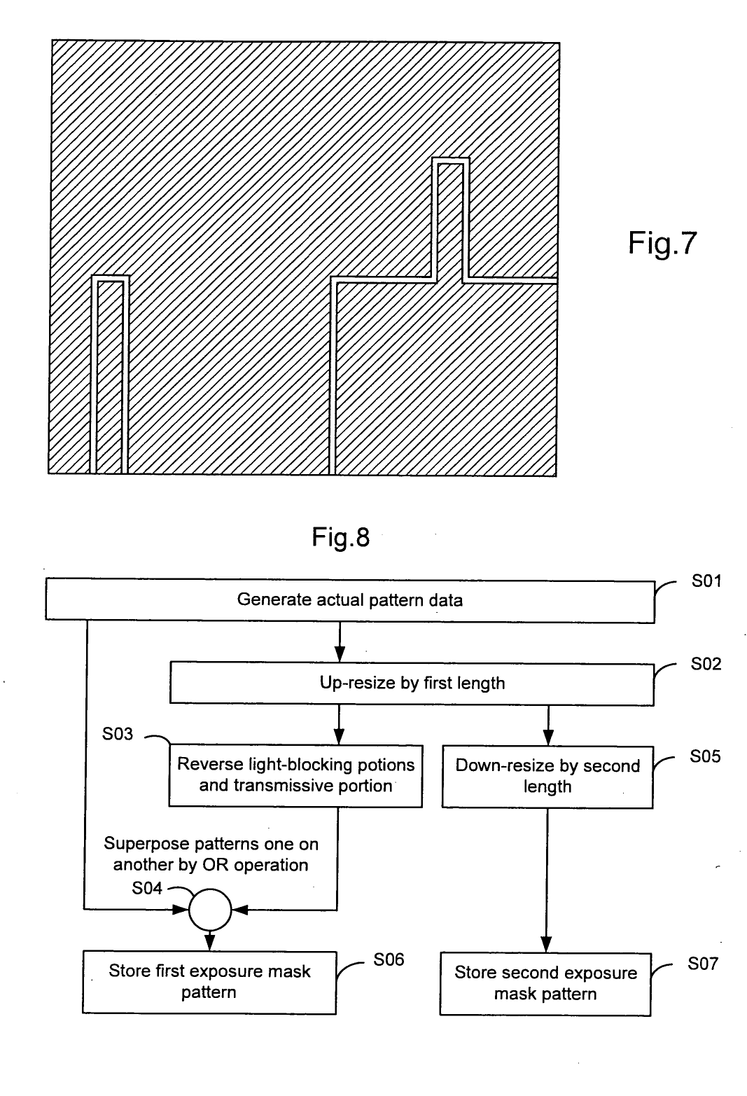

FIGS. 1 to 6 are diagrams for explaining formation of a first exposure mask pattern and a second exposure mask pattern according to this embodiment. FIG. 7 is an explanatory diagram illustrating the first and second exposure mask patterns superposed one on another according to this embodiment.

FIG. 8 is a flow chart for explaining a process for forming the first and second exposure mask patterns according to this embodiment. Patterns shown in FIGS. 1 to 6 correspond to the respective steps in the flow chart shown in FIG. 8.

An explanation will be given to an exposure mask pattern formation method according to this preferred embodiment, wherein a dummy pattern is provided in the vicinity of outer peripheries of a repetitive pattern (L/S pattern) and an isolated pattern to provide a pattern arrangement similar to that of the L/S pattern.

First, actual pattern data for an actual pattern of an exposure mask M shown in FIG. 1, i.e., pattern data for a pattern to be formed on a photoresist layer on a semiconductor wafer, is generated (Step S01).

As shown in FIG. 1, the actual pattern of the exposure mask M indicated by the actual pattern data includes light-blocking portions A1, A2 and a transmissive portion B. The light-blocking portion A1 corresponds to an isolated pattern, and the light-blocking portions A2 respectively correspond line patterns of the L/S pattern.

First pattern data for a first pattern shown in FIG. 2 is generated by graphic processing of the actual pattern data for uniformly enlarging the light-blocking portions A1, A2 of the actual pattern (FIG. 1) (Step S02).

In this graphic processing, the actual pattern data is processed so that the X- and Y-coordinates of the vertexes of the light-blocking portions of the actual pattern are increased or reduced by a predetermined amount to shift the vertexes of the respective light-blocking portions outward. This process is hereinafter referred to as “up-resizing”. If the up-resizing amount is greater than the widths of spaces defined between the line patterns, the resulting line patterns are merged into a single rectangular pattern as indicated by a reference character K in FIG. 2.

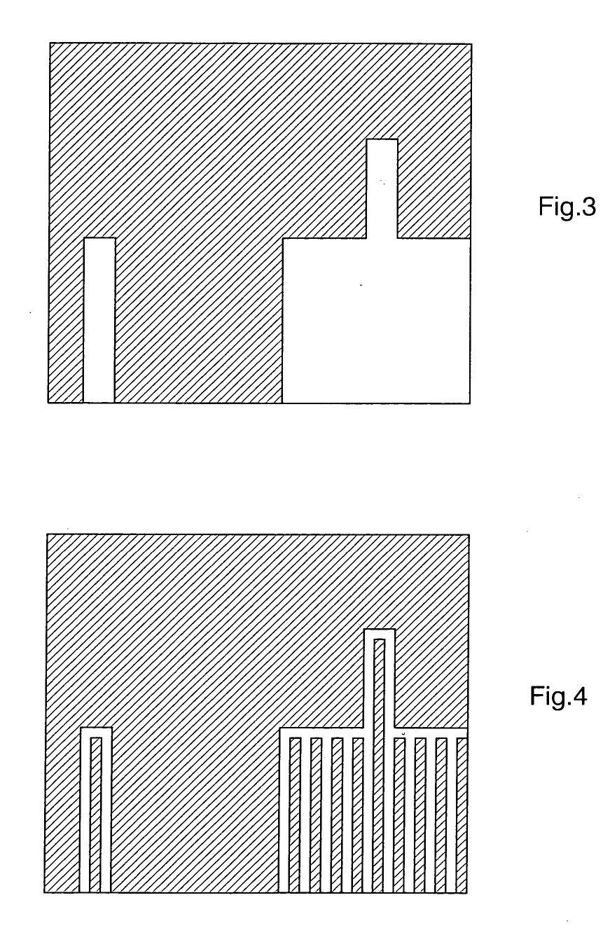

In turn, dummy pattern data for a dummy pattern shown in FIG. 3 is generated by graphic processing of the first pattern data for the first pattern for reversing light blocking portions and a transmissive portion of the first pattern in the entire mask region (Step S03).

Then, pattern data for a superpose pattern shown in FIG. 4 is generated by graphic processing of the actual pattern data and the dummy pattern data for superposing the dummy pattern (FIG. 3) on the actual pattern (FIG. 1) (Step S04). In this graphic processing, the actual pattern data and the dummy pattern data are ORed to generate the pattern data for the superpose pattern.

The pattern data thus generated is employed as pattern data for a first exposure mask to be used for the first photo-exposure. The first exposure mask is provided by forming a first exposure mask pattern on the basis of the pattern data (Step S06).

Where a positive photoresist is employed in the first photo-exposure, a photoresist layer is exposed and etched with the use of the first exposure mask. Thus, a portion of the photoresist layer corresponding to the first exposure mask pattern remains, whereby a photoresist pattern is formed as corresponding to the mask pattern.

Further, pattern data for a pattern shown in FIG. 6 is generated by graphic processing of the first pattern data for uniformly reducing the light-blocking portions of the first pattern (FIG. 2) (Step S05).

This process is hereinafter referred to as “down-resizing”. The pattern data thus generated is employed as pattern data for a second exposure mask to be used for the second photo-exposure. The second exposure mask is provided by forming a second exposure mask pattern on the basis of the pattern data (Step S07).

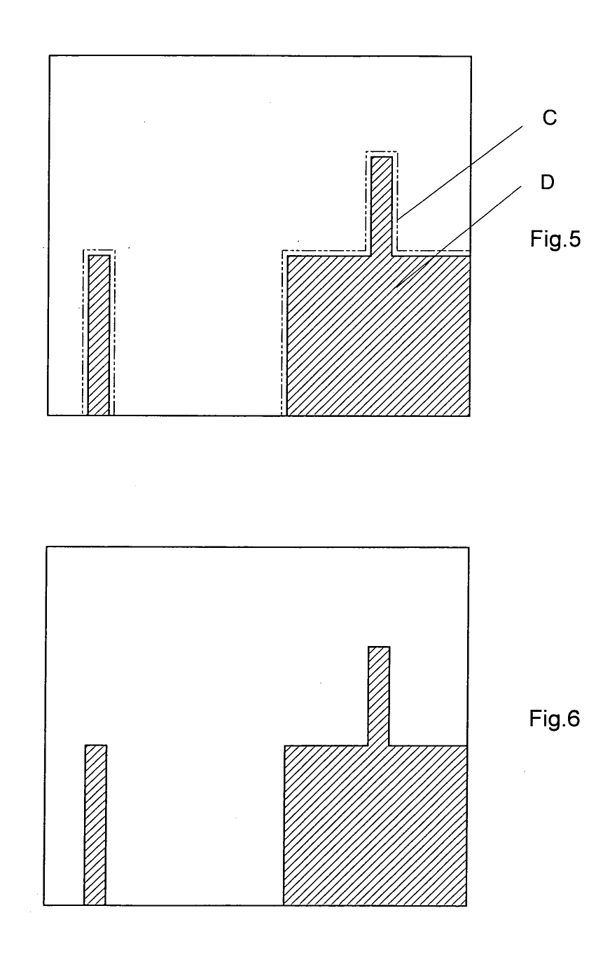

In FIG. 5, the second exposure mask pattern is illustrated with respect to peripheral edges of the dummy pattern of the first exposure mask pattern. A broken line C denotes the peripheral edges of the dummy pattern, and a reference character D denotes light-blocking portions of the second exposure mask pattern.

FIG. 7 illustrates the first exposure mask pattern and the second exposure mask pattern superposed one on another.

As shown in FIG. 5, peripheral edges of the light-blocking portions D of the second exposure mask pattern are located intermediate between the actual pattern and the dummy pattern of the first exposure mask pattern. A space between the actual pattern and the dummy pattern is determined by the up-resizing amount (first length) employed in the up-resizing process in Step S02. Since an alignment margin (an offset allowable for superposing the mask) of the second exposure mask pattern is one half the space defined between the actual pattern and the dummy pattern, a down-resizing amount (first length) to be employed in the up-resizing in Step S02 should be determined in consideration of the alignment margin.

In this mask pattern formation method, the pattern for the first exposure mask including the actual pattern and the dummy pattern provided around the actual pattern can automatically be formed by the graphic processing for any LSI patterns including the pattern employed in this embodiment. Further, the second exposure mask pattern for deleting a photoresist latent image or a photoresist pattern formed according to the dummy pattern of the first exposure mask can automatically be formed.

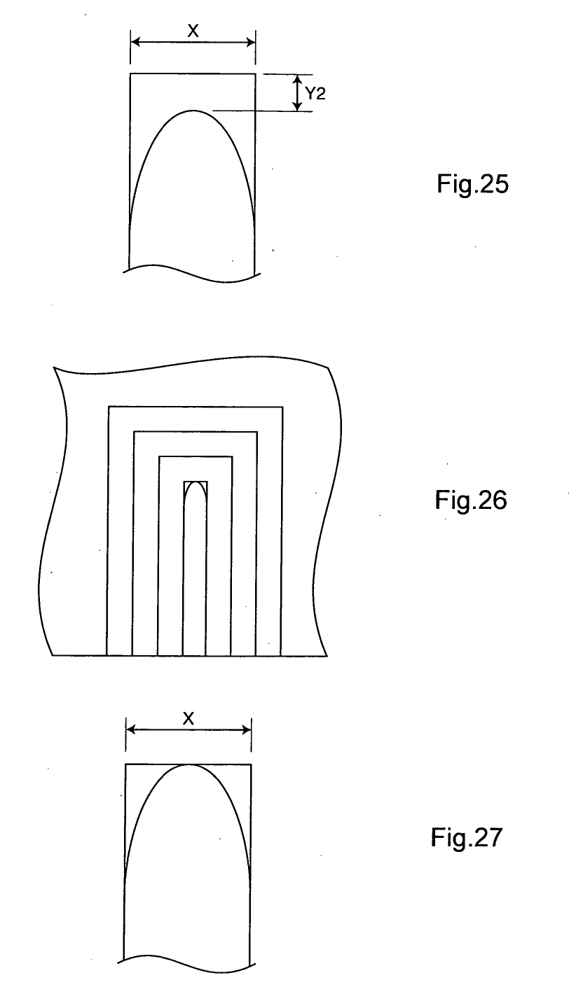

Since the first exposure mask pattern formed by this mask pattern formation method includes the dummy pattern spaced a distance not greater than the first length from the outer peripheries of the light-blocking portions of the actual pattern, interference between light rays leaked from halftone portions located around the light-blocking potions of the actual pattern and 1-order diffracted light rays occurs in a similar manner to the interference occurring in the case of the L/S pattern. Therefore, the focus margins for the L/S pattern and the isolated pattern are improved. In addition, light rays diffracted at distal potions of the line patterns are corrected, whereby the shrinkage of the distal portions is suppressed as shown in FIGS. 24 and 25 (Y2<Y1 in comparison with FIG. 23). Further, the pattern density around the actual pattern of the first exposure mask is made uniform as in the case of the L/S pattern by the provision of the dummy pattern, so that an etching dimensional error attributable to the loading effect can be suppressed in an etching step.

### Second embodiment

An explanation will be given to an exposure mask pattern formation method according to another preferred embodiment, wherein a dummy pattern is provided around a repetitive pattern (L/S pattern) and an isolated pattern to provide a pattern arrangement similar to that of the L/S pattern.

In this embodiment, the up-resizing amount employed in the up-resizing (Step S02) is increased as compared with the first embodiment, and dummy pattern data is generated by data processing for providing a double dummy pattern around the light-blocking portions of the actual pattern.

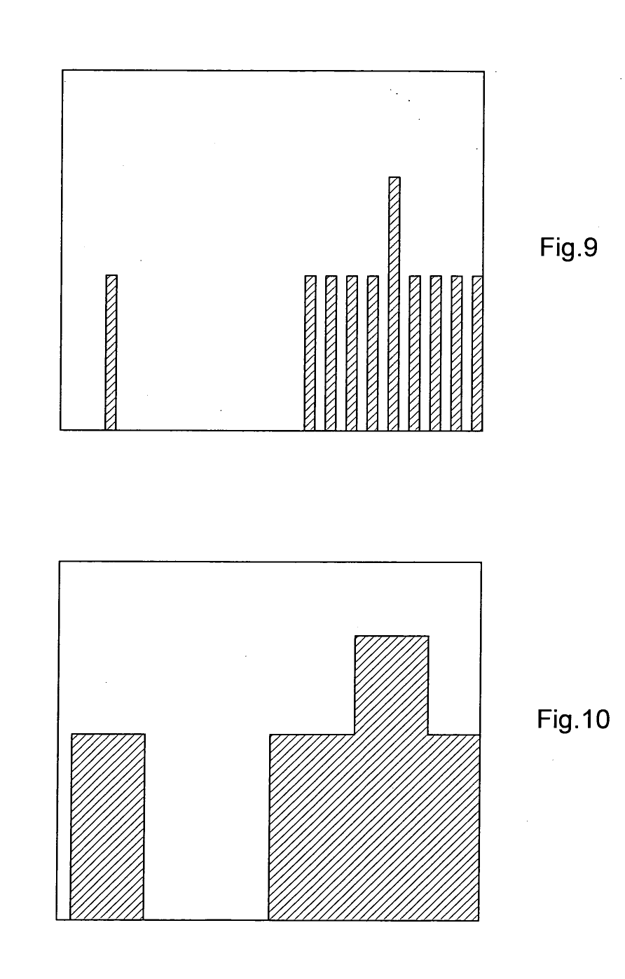

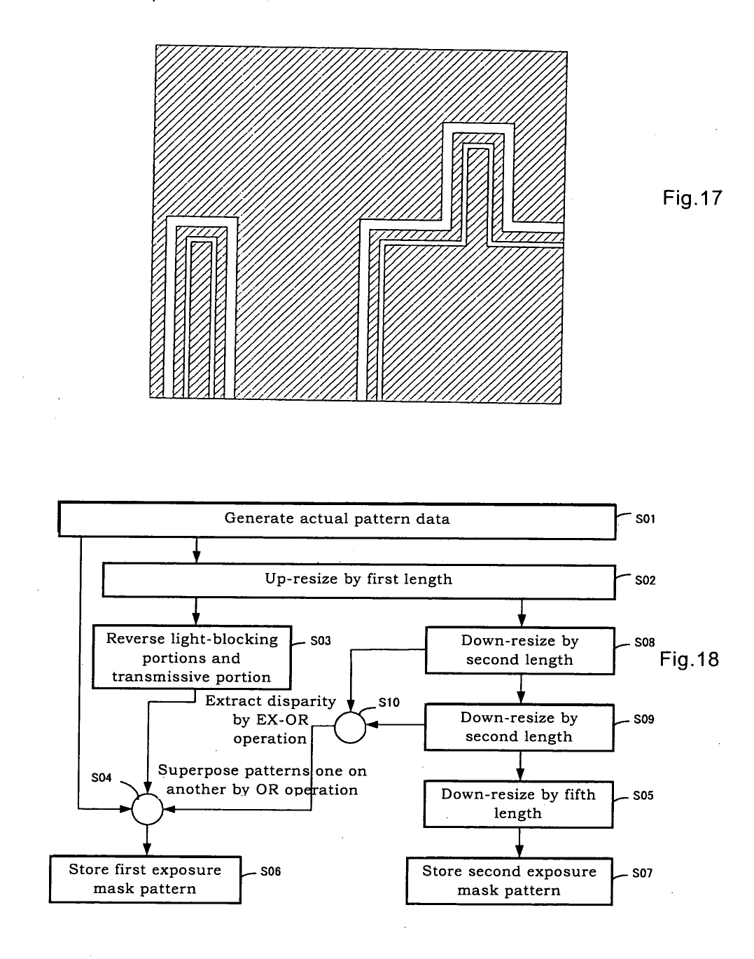

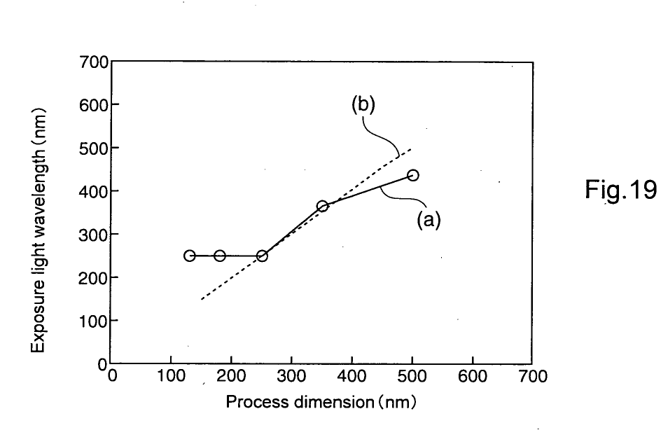

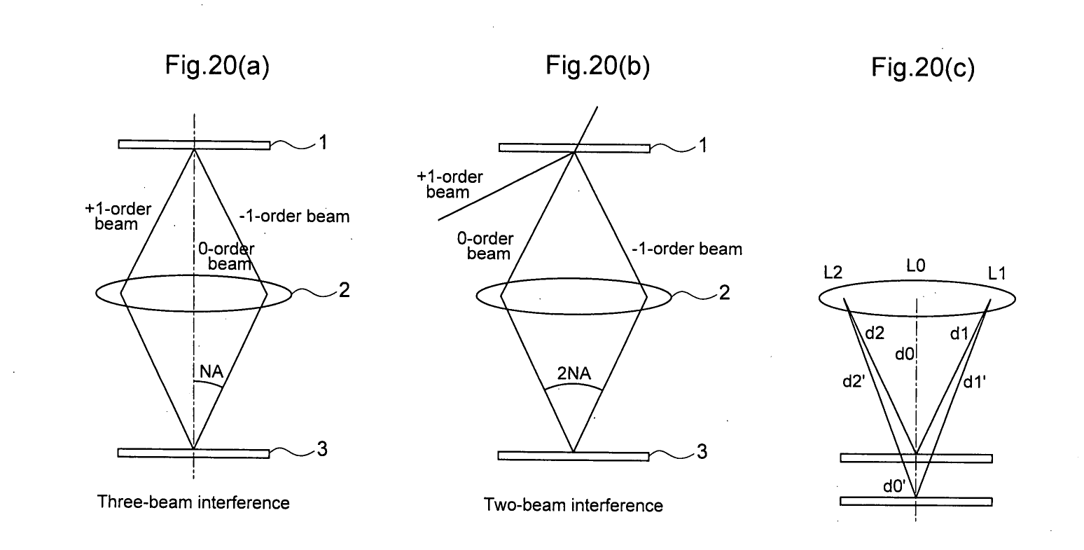

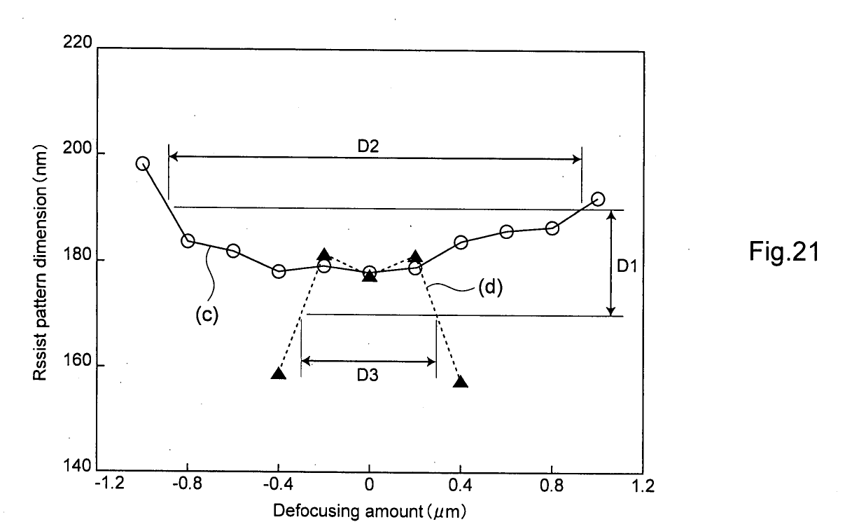

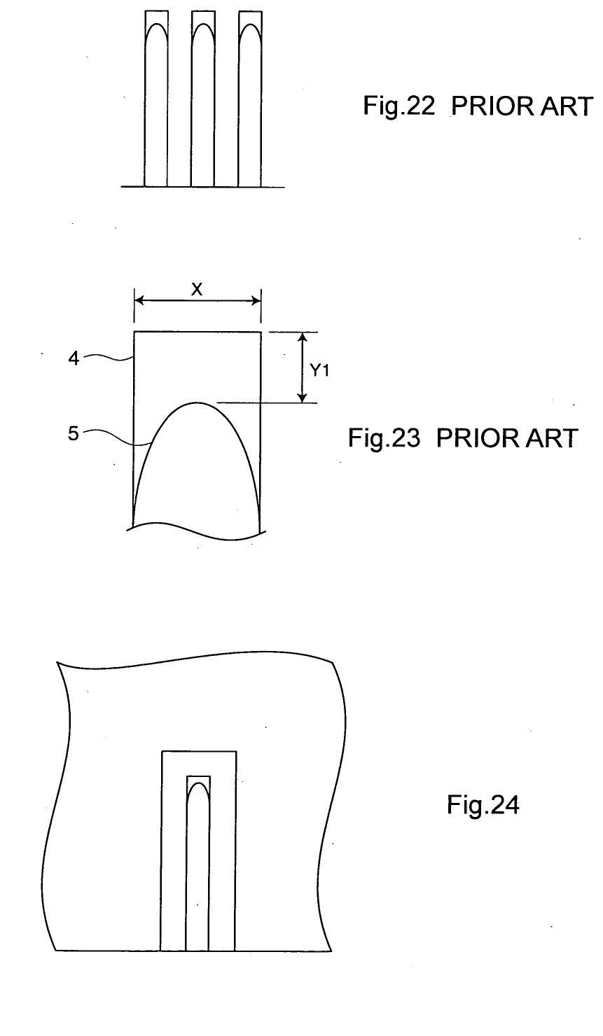

FIGS. 9 to 16 are diagrams for explaining formation of a first exposure mask pattern and a second exposure mask pattern according to this embodiment. FIG. 17 is an explanatory diagram illustrating the first exposure mask pattern and the second exposure mask pattern superposed one on another according to this embodiment. FIG. 18 is a flow chart for explaining a process for forming the first and second exposure mask patterns according to this embodiment.

Patterns shown in FIGS. 9 to 16 correspond to the respective steps in the flow chart shown in FIG. 18. In FIG. 18, steps corresponding to the steps shown in FIG. 8 are denoted by the same step numbers as in FIG. 8. A major difference from FIG. 8 is that Steps S08 to S10 are added in FIG. 18.

First, actual pattern data for an actual pattern shown in FIG. 9 is generated as in the first embodiment (Step S01).

The actual pattern data is processed for up-resizing of the actual pattern, whereby first pattern data for a first pattern shown in FIG. 10 is generated (Step S02).

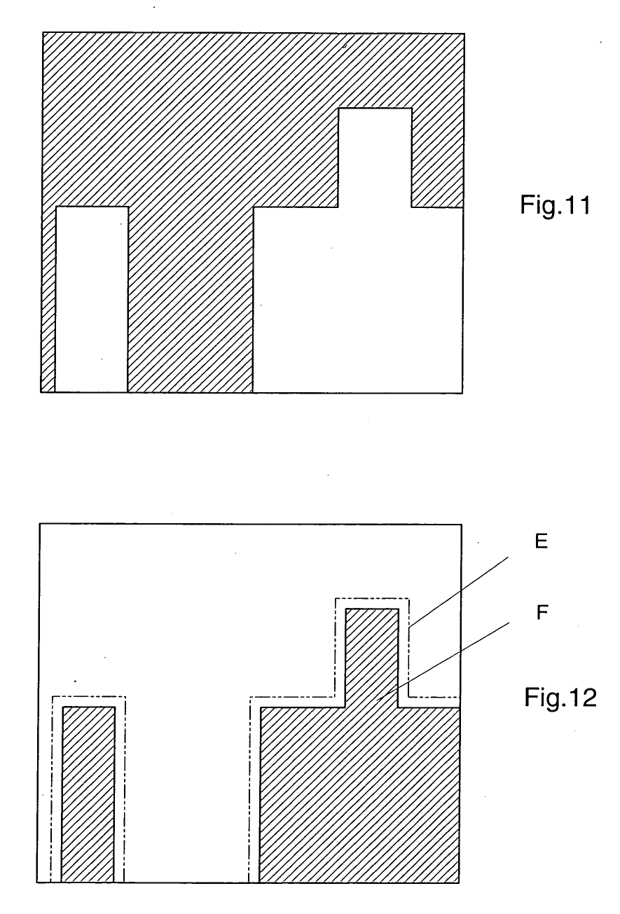

Further, the first pattern data generated by the up-resizing in Step S02 is processed to reverse light-blocking portions and a transmissive portion of the first pattern as shown in FIG. 11, whereby first dummy pattern data for a first dummy pattern shown in FIG. 11 is generated (Step S03).

In turn, the first pattern data is processed for down-resizing of the first pattern (FIG. 10) to reduce the light-blocking portions of the first pattern by a second length, whereby second pattern data for a second pattern shown in FIG. 12 is generated (Step S08). In FIG. 12, a broken line E denotes peripheral edges of the light-blocking portions of the first pattern, and a reference character F denotes light-blocking portions of the second pattern.

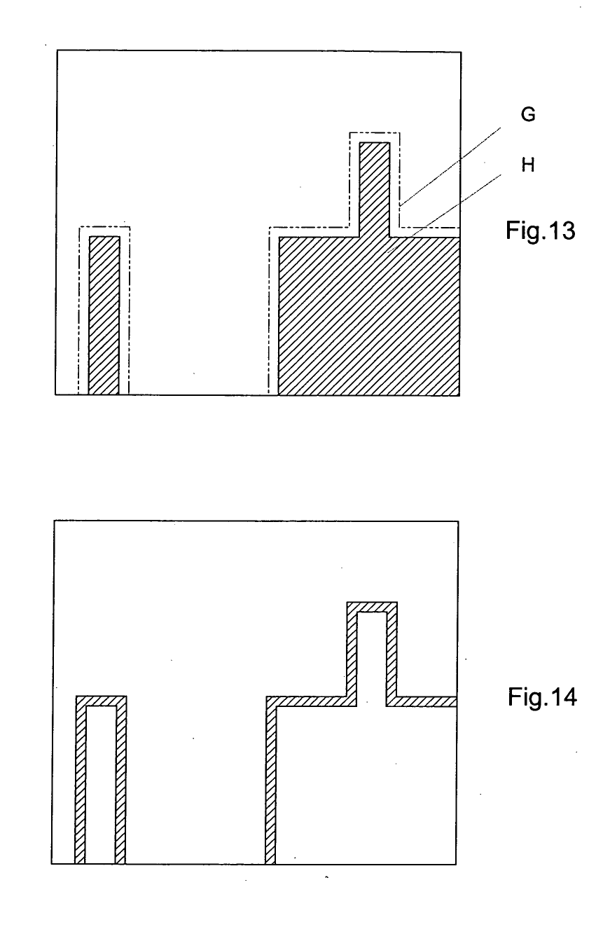

Further, the second pattern data is processed for down-resizing of the second pattern (FIG. 12) to reduce the light-blocking portions of the second pattern by a third length, whereby third pattern data for a third pattern shown in FIG. 13 is generated (Step S09). In FIG. 13, a broken line G denotes peripheral edges of the light-blocking portions of the second pattern, and a reference character H denotes light-blocking portions of the third pattern.

Here, the sum of the second length and the third length as the down-resizing amounts employed in Steps S08 and S09 is determined so that the light-blocking portions of the third pattern are not reduced to smaller than the light-blocking portions of the actual pattern (FIG. 9).

In turn, second dummy pattern data for a second dummy pattern shown in FIG. 14 is generated by graphic processing of the second pattern data and the third pattern data for leaving a disparity between the second pattern (FIG. 12) and the third pattern (FIG. 13) (Step S10). In this graphic processing, the second pattern data and the third pattern data are EX-ORed, whereby the disparity between the second and third patterns is extracted.

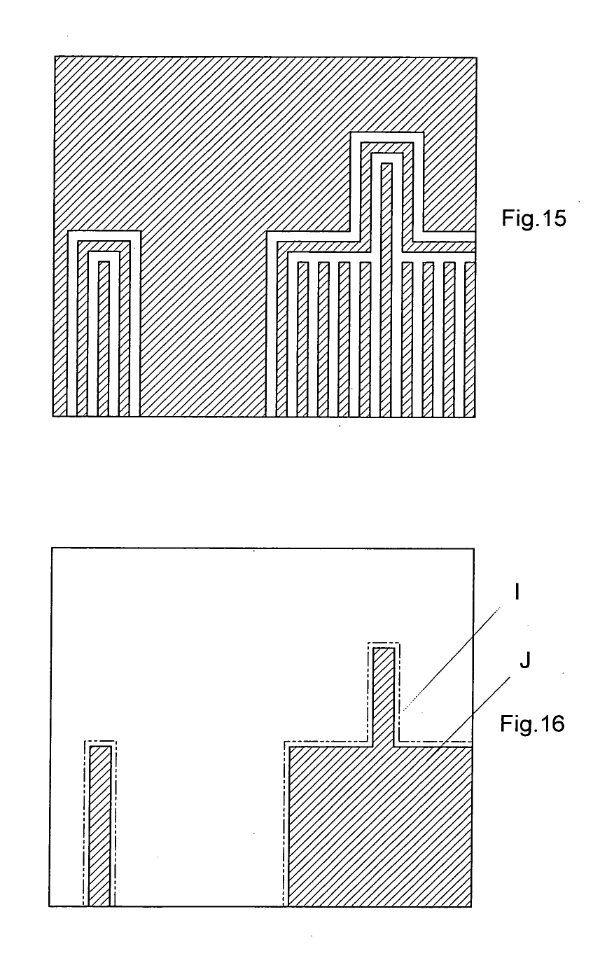

Then, pattern data for a first exposure mask pattern shown in FIG. 15 is generated by graphic processing of the actual pattern data, the first dummy pattern data and the second dummy pattern data for superposing the first dummy pattern (FIG. 11) and the second dummy pattern (FIG. 12) on the actual pattern (FIG. 9) (Step S04). In this graphic processing, the actual pattern data, the first dummy pattern data and the second dummy pattern data are ORed to superpose the first dummy pattern and the second dummy pattern on the actual pattern. A first exposure mask is formed on the basis of the pattern data thus generated for the first exposure mask pattern (Step S06).

Further, the third pattern data is processed for down-resizing of the third pattern (FIG. 13) to reduce the light-blocking portions of the third pattern by a fifth length, whereby pattern data for a second exposure mask pattern shown in FIG. 16 is generated (Step S05). In FIG. 16, a broken line I denotes peripheral edges of the light-blocking portions of the third pattern, and a reference character J denotes light-blocking portions of the second exposure mask pattern.

A second exposure mask is formed on the basis of the pattern data thus generated for the second exposure mask pattern (Step S07).

Since the first exposure mask pattern formed by this mask pattern formation method includes the second dummy pattern spaced a predetermined distance from the peripheral edges of the light-blocking portions of the actual pattern and having light-blocking portions of a predetermined width and the first dummy pattern spaced a predetermined distance from the second dummy pattern, interference between light rays leaked from halftone portions located around the light-blocking potions of the actual pattern and 1-order diffracted light rays occurs in a similar manner to the interference occurring in the case of the L/S pattern. Therefore, the focus margins for the L/S pattern and the isolated pattern are further improved. In addition, light rays diffracted at distal potions of the line patterns are corrected, whereby the shrinkage of the distal portions is effectively suppressed as shown in FIGS. 26 and 27. Further, the pattern density around the actual pattern of the first exposure mask is made uniform as in the case of the L/S pattern by the provision of the dummy patterns, so that an etching dimensional error attributable to the loading effect can effectively be suppressed in an etching step.

To maximize the focus margin improving effect, the widths of spaces in the first exposure mask pattern shown in FIG. 15 may be made closer to the widths of the inter-line spaces of the L/S pattern. This is achieved by adjusting the up-resizing amount employed in Step S02 and the down-resizing amounts employed in Steps S08 and S09. However, it should be noted that, where the second dummy pattern shown in FIG. 15 has the same width as the line patterns of the actual pattern, a photoresist pattern corresponding to the second dummy pattern is formed.

A plurality of second dummy patterns may be formed by repeating the down-resizing and the disparity extraction (Steps S08, S09 and S10) in the second embodiment. This makes it possible to provide a pattern arrangement similar to that of the L/S pattern around the actual pattern, but the number of the steps for the pattern formation is increased. In view of this, it is practical to perform this pattern formation process for the improvement of the focus margin characteristics for the peripheral portion of the L/S pattern, the distal portions of the line patterns and the isolated pattern and for the suppression of the etching dimensional error attributable to the loading effect can be ensured.

### Third embodiment

According to the present invention, photoresist patterns formed as corresponding to the dummy patterns by the first exposure with the use of the first exposure mask are liable to remain on the wafer. Therefore, an explanation will be given to a. process for removing the photoresist patterns corresponding to the dummy patterns according to this embodiment.

Where patterns formed in an LSI according to the photoresist patterns corresponding to the dummy patterns cause no functional problem, the dummy photoresist patterns need not be removed, but may be left as they are. In a device isolation step, a gate formation step or the like in a transistor production process, it is functionally problematic to leave the patterns formed according to the dummy photoresist patterns. In a metallization step, however, the patterns formed according to the dummy photoresist patterns may be left. Since the dummy patterns are formed by the processing shown in FIGS. 8 and 18, there is no possibility that interconnection patterns corresponding to the dummy patterns are electrically shorted with interconnection patterns corresponding to the actual pattern. That is, the dummy interconnection patterns are floated to be completely electrically isolated from the actual interconnection patterns. As long as an adverse influence such as a signal transmission delay is not caused by an inter-line capacitance attributable to the dummy interconnection patterns, the dummy interconnection patterns may be left unremoved. In this case, the dummy photoresist patterns are present on the wafer in an etching step after the photo-exposure, so that the pattern density can be made uniform and variations in post-etching line pattern width and other dimensional variations due to the loading effect can effectively be reduced.

Where the formation of the patterns corresponding to the dummy patterns should be prevented because of the functional problem, latent image patterns corresponding to the dummy patterns may be deleted by performing the second photo-exposure with the use of the second exposure mask after the first photo-exposure performed with the use of the first exposure mask. In this case, when an etching process is performed, only the photoresist patterns corresponding to the actual pattern is formed, but the dummy photoresist patterns are not formed. Therefore, no additional step is thereafter required. In this case, the loading effect in the etching step cannot be suppressed, but variations in line pattern width, other dimensional variations and the shrinkage of the distal portions of the line patterns in the photoresist pattern formation step can be suppressed as in the third embodiment.

Where the function of the semiconductor device is adversely influenced by the patterns corresponding to the dummy patterns of the first exposure mask, the formation of the patterns can be prevented in the aforesaid manner.

### Fourth embodiment

An explanation will hereinafter be given to a process for processing patterns formed as corresponding to the dummy patterns by the first photo-exposure according to further another embodiment.

In this process, first etching is carried out, while the patterns corresponding to the dummy patterns formed with the use of the first exposure mask are left unremoved. Thereafter, the second photo-exposure is carried out with the use of the second exposure mask, and then second etching is carried out to remove the patterns corresponding to the dummy patterns. In this case, the number of steps is increased, but variations in line pattern width and other dimensional variations can effectively be reduced both in the photo-exposure step and in the etching step. Since the patterns formed as corresponding to the dummy patterns are finally removed in the second etching step, this process is applicable to all types of masks.

Where the function of the semiconductor device is adversely influenced by the patterns corresponding to the dummy patterns of the first exposure mask, the formation of the patterns can be prevented.

In the inventive mask pattern formation methods, the first and second exposure mask patterns are formed on the basis of the pattern data generated by the graphic processing of the actual pattern data. Therefore, the exposure mask patterns suitable for the resolution improving technique are automatically formed by the simple graphic processing. Thus, the formation of the exposure mask patterns can be achieved in a short period of time with the use of a less expensive tool.

The first exposure mask formed by one of the inventive mask pattern formation methods provides the first exposure mask pattern which includes the dummy pattern spaced a distance not greater than the first length from the outer peripheries of the light-blocking portions of the actual pattern. Therefore, interference between light rays leaked from the halftone portions located around the light-blocking potions of the actual pattern and 1-order diffracted light rays occurs in a similar manner to the 10 interference occurring in the case of the L/S pattern. Hence, the focus margins for the L/S pattern and the isolated pattern are further improved. In addition, light rays diffracted at the distal potions of the line patterns are corrected, whereby the shrinkage of the distal portions is suppressed. Further, the pattern density around the actual pattern is made uniform as in the case of the L/S pattern by the provision of the dummy pattern, so that the etching dimensional error attributable to the loading effect can effectively be suppressed. Therefore, the semiconductor device can be produced at a higher yield according to the present invention.

The first exposure mask formed by the other inventive mask pattern formation method provides the first exposure mask pattern which includes the second dummy pattern spaced a predetermined distance from the outer peripheries of the light-blocking portions of the actual pattern and having the light-blocking portions of a predetermined width and the first dummy pattern spaced a predetermined distance from the second dummy pattern. Therefore, interference between light rays leaked from the halftone portions located around the light-blocking potions of the actual pattern and 1-order diffracted light rays occurs in a similar manner to the interference occurring in the case of the L/S pattern. Hence, the focus margins for the L/S pattern and the isolated pattern are further improved. In addition, light rays diffracted at the distal potions of the line patterns are corrected, whereby the shrinkage of the distal portions is suppressed. Further, the pattern density around the actual pattern is made uniform as in the case of the L/S pattern by the provision of the dummy pattern, so that the etching dimensional error attributable to the loading effect can effectively be suppressed. Therefore, the semiconductor device can be produced at a higher yield according to the present invention.

In the semiconductor device production method, the first and second exposure masks are formed by employing the exposure mask patterns formed by either of the aforesaid exposure mask pattern formation methods, and the photoresist layer on the semiconductor wafer is subjected to the first photo-exposure with the use of the first exposure mask in the first photo-exposure step and then to the second photo-exposure with the use of the second exposure mask in the second photo-exposure step. Therefore, where the function of the semiconductor device is adversely influenced by the pattern corresponding to the dummy pattern of the first exposure mask, the formation of the pattern can be prevented.

In the semiconductor device production method, the photoresist layer is selectively etched away according to the latent image pattern formed therein in the first photo-exposure step to form the photoresist patterns corresponding to the actual pattern and the dummy pattern of the first exposure mask after the first photo-exposure step, and the photoresist patterns are subjected to the second photo-exposure in the second photo-exposure step and then selectively etched away according to the latent image pattern formed therein in the second photo-exposure step. In this case, the photoresist pattern corresponding to the dummy pattern is removed after the etching of the photoresist pattern corresponding to the actual pattern. Therefore, the photoresist pattern corresponding to the actual pattern can be formed, while variations in line pattern width and other dimensional variations are effectively reduced both in the photo-exposure step and in the etching step.

Alternatively, the second photo-exposure step is carried out after the first photo-exposure step, and then the photoresist layer is selectively etched away according to the latent image formed therein as a result of the first photo-exposure and the second photo-exposure in the semiconductor device production method. In this case, the latent image formed as corresponding to the dummy pattern in the photoresist layer is deleted, so that only the photoresist pattern corresponding to the actual pattern can be formed without the need for additional step.

What is claimed is:

1. An exposure mask pattern formation method which comprises the steps of:
(a) providing actual pattern data for an actual pattern of an exposure mask having a light-blocking portion and a transmissive portion;
(b) making first pattern data for a first pattern by graphic processing of the actual pattern data for uniformly enlarging the light-blocking portion of the actual pattern by a first length;
(c) making dummy pattern data for a dummy pattern by graphic processing of the first pattern data for reversing a light-blocking portion and a transmissive portion of the first pattern;
(d) making pattern data for a first exposure mask by graphic processing of the actual pattern data and the dummy pattern data for superposing the dummy pattern on the actual pattern, wherein the dummy pattern at its outer periphery opposing to the light-blocking portion of the actual pattern is spaced a distance not greater than the first length from an outer periphery of the light-blocking portion of the actual pattern in the first exposure mask; and
(e) forming a first exposure mask pattern on the basis of the pattern data made in the step (d).

2. An exposure mask pattern formation method as set forth in claim 1, further comprising the steps of:
(f) making pattern data for a second exposure mask including a transmissive portion entirely covering a region thereof corresponding to the dummy pattern of the first exposure mask by graphic processing of the first pattern data for uniformly reducing the light-blocking portion of the first pattern by a second length; and
(g) forming a second exposure mask pattern on the basis of the pattern data made in the step (f).

3. An exposure mask pattern formation method comprising the steps of:
(a) providing actual pattern data for an actual pattern of an exposure mask including a light-blocking portion and a transmissive portion;
(b) making first pattern data for a first pattern by graphic processing of the actual pattern data for uniformly enlarging the light-blocking portion of the actual pattern by a first length (L1);
(c) making first dummy pattern data for a first dummy pattern by graphic processing of the first pattern data for reversing a light-blocking portion and a transmissive portion of the first pattern;
(d) making second pattern data for a second pattern by graphic processing of the first pattern data for uniformly reducing the light-blocking portion of the first pattern by a second length (L2);
(e) making third pattern data for a third pattern by graphic processing of the second pattern data for uniformly reducing a light-blocking portion of the second pattern by a third length (L3);
(f) making second dummy pattern data for a second dummy pattern by graphic processing of the second pattern data and the third pattern data for extracting a disparity between the second pattern and the third pattern;
(g) making pattern data for a first exposure mask by graphic processing of the actual pattern data, the first dummy pattern data and the second dummy pattern data for superposing the first dummy pattern and the second dummy pattern on the actual pattern, wherein the second dummy pattern at its outer periphery opposing to the light-blocking portion of the actual pattern is spaced a distance L1-L2-L3 from an outer periphery of the light-blocking portion of the actual pattern and has a linear light-blocking portion having a width of not greater than L2, and the first dummy pattern at its outer periphery opposing to the light-blocking portion of the second dummy pattern is spaced a distance L2 from the outer periphery of the second dummy pattern in the first exposure mask; and
(h) forming a first exposure mask pattern on the basis of the pattern data made in the step (g).

4. An exposure mask pattern formation method as set forth in claim 3, further comprising the steps of:
(i) making pattern data for a second exposure mask including a transmissive portion entirely covering a region thereof corresponding to the first and second dummy patterns of the first exposure mask by graphic processing of the third pattern data for uniformly reducing a light-blocking portion of the third pattern by a fourth length; and
(j) forming a second exposure mask pattern on the basis of the pattern data made in the step (i).

5. An exposure mask pattern formation method as set forth in claim 3, wherein the sum of the second length L2 and the third length L3 is not greater than the first length L1.

6. A first exposure mask which is prepared by employing the first exposure mask pattern formation method of claim 1.

7. A second exposure mask which is prepared by employing the second exposure mask pattern formation method of claim 2.

8. A semiconductor device production method utilizing photolithography, the method comprising the steps of:
forming a first exposure mask by employing the first exposure mask pattern formation method of claim 1, and forming a second exposure mask by employing the second exposure mask pattern formation method of claim 2;
subjecting a photoresist layer on a semiconductor wafer to first photo-exposure with the use of the first exposure mask; and
subjecting the photoresist layer on the semiconductor wafer to second photo-exposure with the use of the second exposure mask.

9. A semiconductor device production method as set forth in claim 8,
wherein the second photo-exposure step is performed after the first photo-exposure step,
the production method further comprising the step of, after the second photo-exposure step, selectively etching away the photoresist layer according to a latent image formed in the photoresist layer as a result of the first photo-exposure and the second photo-exposure to form a photoresist pattern corresponding to an actual pattern of the first exposure mask on the semiconductor wafer.

10. A semiconductor device production method as set forth in claim 8, further comprising the steps of:
after the first photo-exposure step, selectively etching away the photoresist layer according to a latent image formed in the photoresist layer in the first photo-exposure step to form photoresist patterns corresponding to an actual pattern and a dummy pattern of the first exposure mask; and
after the second exposure step, selectively etching away the photoresist layer according to a latent image formed in the photoresist layer in the second photo-exposure step to selectively remove the photoresist pattern corresponding to the dummy pattern.

11. A first exposure mask which is prepared by employing the first exposure mask pattern formation method of claim 3.

12. A second exposure mask which is prepared by employing the second exposure mask pattern formation method of claim 4.

13. A semiconductor device production method utilizing photolithography, the method comprising the steps of:
forming a first exposure mask by employing the first exposure mask pattern formation method of claim 3, and forming a second exposure mask by employing the second exposure mask pattern formation method of claim 4;
subjecting a photoresist layer on a semiconductor wafer to first photo-exposure with the use of the first exposure mask; and
subjecting the photoresist layer on the semiconductor wafer to second photo-exposure with the use of the second exposure mask.

14. A semiconductor device production method as set forth in claim 13,
wherein the second photo-exposure step is performed after the first photo-exposure step,
the production method further comprising the step of, after the second photo-exposure step, selectively etching away the photoresist layer according to a latent image formed in the photoresist layer as a result of the first photo-exposure and the second photo-exposure to form a photoresist pattern corresponding to an actual pattern of the first exposure mask on the semiconductor wafer.

15. A semiconductor device production method as set forth in claim 13, further comprising the steps of:
after the first photo-exposure step, selectively etching away the photoresist layer according to a latent image formed in the photoresist layer in the first photo-exposure step to form photoresist patterns corresponding to an actual pattern and a dummy pattern of the first exposure mask; and
after the second exposure step, selectively etching away the photoresist layer according to a latent image formed in the photoresist layer in the second photo-exposure step to selectively remove the photoresist pattern corresponding to the dummy pattern.
